(19) United States
(12) Patent Application Publication
(10) Pub. No.: US 2014/0077661 A1
(43) Pub. Date: Mar. 20, 2014

(54) VIBRATING ACTUATOR

(71) Applicant: SAMSUNG ELECTRO-MECHANICS CO., LTD., Suwon (KR)

(72) Inventors: Viatcheslav SMIRNOV, Suwon (KR); Hwa Young OH, Suwon (KR)

(73) Assignee: SAMSUNG ELECTRO-MECHANICS CO., LTD., Suwon (KR)

(21) Appl. No.: 13/683,499

(22) Filed: Nov. 21, 2012

(30) Foreign Application Priority Data
Sep. 19, 2012 (KR) 10-2012-0104224

(51) Int. Cl. H01L 41/09

(52) U.S. Cl. CPC H01L 41/0926
USPC 310/329

(57) ABSTRACT

There is provided a vibrating actuator including: a housing including an inner space; a piezoelectric element mounted on a portion of an inner surface of the housing; a mass body disposed above the piezoelectric element; a first elastic member disposed between the piezoelectric element and the mass body to elastically support the mass body; and a second elastic member having one end joined to the housing and the other end joined to the mass body to elastically support the mass body.

### CROSS-REFERENCE TO RELATED APPLICATIONS

This application claims the priority of Korean Patent Application No. 10-2012-0104224 filed on Sep. 19, 2012, in the Korean Intellectual Property Office, the disclosure of which is incorporated herein by reference.

### BACKGROUND OF THE INVENTION

1. Field of the Invention

The present invention relates to a vibrating actuator, and more particularly, to a vibrating actuator using a piezoelectric element.

2. Description of the Related Art

Recently, personal digital assistants (PDAs), provided with large LCD screens for user convenience, have become wide spread. In relation thereto, touchscreens have been adopted for use in PDAs, using vibrating motors for generating vibrations at the time of touch.

The vibrating motor, a component that converts electrical energy into mechanical vibrations using the principle of the generation of electromagnetic force, is mounted in a vibrated body such as that of a PDA, to be used for silently informing a user of call receipt.

In the related art, the vibrating motor uses a brush type structure having a commutator, periodically generating electromagnetic force meeting a resonance frequency to generate vibrations.

However, the brush type structure having the commutator may cause mechanical friction and electrical sparks as well as generating foreign objects while the brush passes through segments of the commutator and a gap between the segments at the time of motor rotation, thereby shortening motor lifespan and taking an excessive time to reach a target vibration quantity, due to a rotational inertia when voltage is applied to a motor, such that it may be difficult to implement an appropriate amount of vibrations in a touchscreen.

Further, linear vibrators may have a defect in that performance and characteristics thereof may vary due to contact between components vibrated in an inner space and noise generated thereby, which affects performance of portable electronic devices adopting the linear vibrator.

Therefore, research into a vibrating actuator that can be slimmed and efficiently produced and does not affect the performance and characteristics of the vibrator even in a case in which several factors may be applied thereto, so as to meet market demands for miniaturization and slimness in portable electronic devices, is needed.

The invention disclosed in the following Related Art Document relates to a vibrating generator generating vibrations using a piezoelectric element.

### RELATED ART DOCUMENT

Korean Patent No. 0639024

### SUMMARY OF THE INVENTION

An aspect of the present invention provides a vibrating actuator capable of satisfying requirements for miniaturization and slimness, increasing a quantity of vibrations, and reducing power consumption.

According to an aspect of the present invention, there is provided a vibrating actuator, including: a housing including an inner space; a piezoelectric element mounted on a portion of an inner surface of the housing; a mass body disposed above the piezoelectric element; a first elastic member disposed between the piezoelectric element and the mass body to elastically support the mass body; and a second elastic member having one end joined to the housing and the other end joined to the mass body to elastically support the mass body.

The piezoelectric element may be configured of a single piezoelectric layer.

The piezoelectric element may be configured of a plurality of piezoelectric layers.

The portion of the inner surface of the housing may be provided with an outer wall protruded to correspond to an outer diameter of the piezoelectric element.

The mass body may be provided with a contact preventing portion in which at least a portion of a bottom surface of the mass body is recessed upwardly.

A radial surface of the housing may be attached to a vibrated body and the mass body may be vibrated vertically with respect to the vibrated body.

A vertical surface of the housing may be attached to the vibrated body and the mass body may be vibrated radially with respect to the vibrated body.

The mass body may be provided with a support portion protruded radially outwardly from a lower portion of the mass body.

The second elastic member may be joined to the support portion.

A top surface of the mass body may be provided with a groove provided in a circumferential direction and the second elastic member may be accommodated in the groove.

The mass body may be provided with a protrusion formed by upwardly protruding at least one of the top surface of the mass body, and the protrusion may be joined to the second elastic member.

The mass body may include a horizontal portion and a vertical portion extending axially upwardly and downwardly from an outside of the horizontal portion.

The other surface inside the housing may be provided with a protrusion protruded to have an outer diameter smaller than an inner diameter of the vertical portion.

According to another aspect of the present invention, there is provided a vibrating actuator, including: a housing including an inner space; a piezoelectric element mounted on a portion of an inner surface of the housing; a mass body disposed above the piezoelectric element; a first elastic member contacting the piezoelectric element and the mass body to elastically support the mass body; and a second elastic member contacting the mass body and the housing to elastically support the mass body.

The mass body may include a horizontal portion and a vertical portion extending axially upwardly and downwardly from both ends of the horizontal portion.

The mass body and the housing may include a sliding film interposed therebetween.

An inner surface of the housing may be provided with a guide portion protruded so as to point-contact the mass body.

The other surface inside the housing may be provided with a protrusion corresponding to an outer diameter of the second elastic member and the inner surface of the protrusion may have the second elastic member inserted thereinto.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating a vibrating actuator according to a first embodiment of the present invention;

FIG. 2 is a flat cross-sectional view of the vibrating actuator according to the first preferred embodiment of the present invention;

FIG. 3 is a schematic cross-sectional view illustrating a modification of a spring of the vibrating actuator according to the first embodiment of the present invention;

FIG. 4 is a schematic cross-sectional view illustrating a vibrating actuator according to a second embodiment of the present invention;

FIG. 5 is a schematic cross-sectional view illustrating a vibrating actuator according to a third embodiment of the present invention;

FIG. 6 is a schematic cross-sectional view illustrating a vibrating actuator according to a fourth embodiment of the present invention;

FIG. 7 is a schematic cross-sectional view illustrating a modification of a piezoelectric element, a first elastic member, and a second elastic member of the vibrating actuator according to the fourth embodiment of the present invention;

FIG. 8 is a schematic cross-sectional view illustrating a vibrating actuator according to a fifth embodiment of the present invention;

FIG. 9 is a schematic cross-sectional view illustrating a vibrating actuator according to a sixth embodiment of the present invention;

FIG. 10 is a schematic cross-sectional view illustrating a modification of a piezoelectric element and a second elastic member of the vibrating actuator according to the sixth embodiment of the present invention;

FIG. 11A is a schematic side cross-sectional view illustrating an appearance in which a vibrating actuator according to a seventh embodiment of the present invention further includes a sliding film;

FIG. 11B is a cross-sectional view taken along line B-B′ of FIG. 11A;

FIG. 12A is a schematic side cross-sectional view illustrating the vibrating actuator according to the seventh embodiment of the present invention;

FIG. 12B is a cross-sectional view taken along line C-C′ of FIG. 12A; and

FIG. 12C is a schematic cross-sectional view illustrating an appearance in which the vibrating actuator according to the seventh embodiment of the present invention further includes a guide portion.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

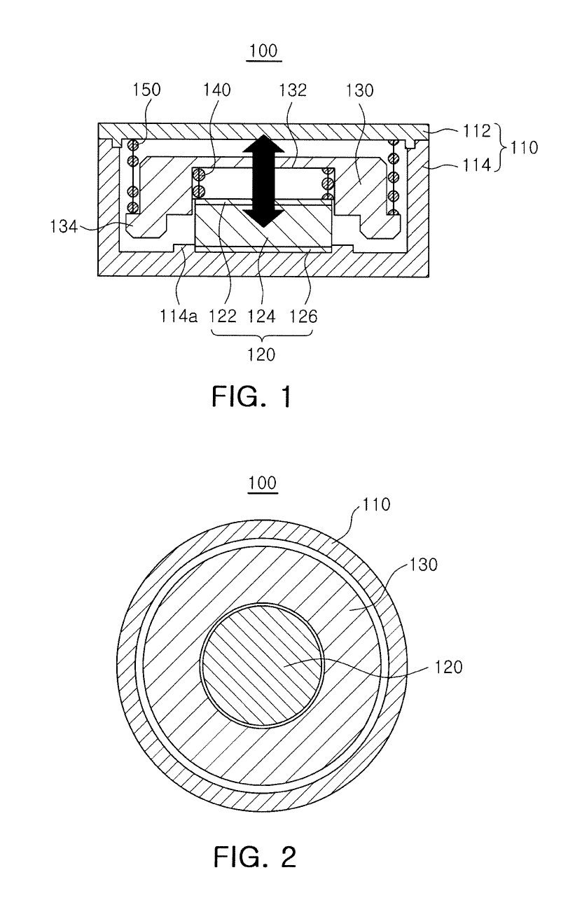

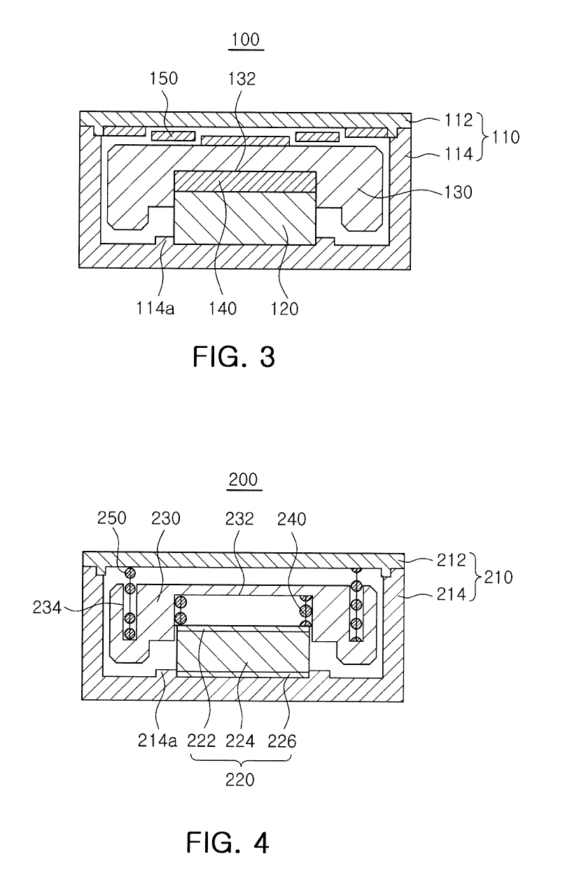

FIG. 1 is a schematic cross-sectional view illustrating a vibrating actuator according to a first embodiment of the present invention, FIG. 2 is a flat cross-sectional view of the vibrating actuator according to the first preferred embodiment of the present invention, and FIG. 3 is a schematic cross-sectional view illustrating a modification of a spring of the vibrating actuator according to the first embodiment of the present invention.

First, when defining terms for directions, a vertical direction may be a direction from a bottom surface of a housing 110 toward a top surface of the housing 110 or a direction opposite thereto and a radial outside or inside direction may be a direction from a center of the housing 110 toward an outer circumferential surface of the housing 110 or vice versa.

Referring to FIGS. 1 through 3, a vibrating actuator 100 according to the first embodiment of the present invention may include the housing 110 forming an outer casing of the vibrating actuator 100, a mass body 130, a first elastic member 140, a second elastic member 150, and a piezoelectric element 120.

The housing 110 may include a lower housing 114 of which one portion is opened and providing a predetermined inner space and an upper housing 112 joined to the opened portion of the lower housing 114.

The inner space may accommodate the mass body 130, the first elastic member 140, the second elastic member 150, the piezoelectric element 120, and the like, and the housing 110 may also integrally be formed.

A portion of the inner surface of the housing 110 may be provided with an outer wall 114a protruded to correspond to an outer diameter of the piezoelectric element 120 to be described below and an inner surface of the outer wall 114a may have the piezoelectric element 120 inserted thereinto to more firmly join the piezoelectric element 120 with the portion of the inner surface of the housing 110.

The housing 110 is attached to a vibrated body as in the case of portable electronic devices and may transfer vibrations from the mass body 130 to be described below to the vibrated body.

The mass body 130 is a component vibrated by the piezoelectric element 120 to be described below and a medium of vibrations in the vibrating actuator 100 according to the first embodiment of the present invention may be configured of the first elastic member 140 and the second elastic member 150.

When the mass body 130 is vibrated, the mass body 130 may be provided to have an outer diameter smaller than an inner diameter with respect to the inner circumferential surface of the housing 110 so as to vibrate without contacting the inner circumference surface of the housing 110.

Therefore, a gap having a predetermined size may be formed between the inner circumferential surface of the housing 110 and the outer circumferential surface of the mass body 130.

The mass body 130 may be formed of a material such as tungsten, having a heavier specific gravity than iron, increasing a mass of the mass body 130 within the same volume to significantly increase a vibration quantity.

However, a material of the mass body 130 is not limited to tungsten and therefore, the mass body 130 may be formed of various materials according to designer's intention.

A shape of a radial cross section of the mass body 130 may be variously formed to have a circular, a rectangular, a regular square, a ring shape, or the like, according to the shape of the housing 110 and the internal components.

The mass body 130 may be disposed above the piezoelectric element 120 to be described below.

Here, the mass body 130 is provided with a contact preventing portion 132 in which at least a portion of a bottom surface of the mass body 130 is recessed upwardly, wherein the contact preventing portion 132 may be provided with the first elastic member 140.

The first elastic member 140 may be disposed between the contact preventing portion 132 and the piezoelectric element 120 to transfer a vibration force of the piezoelectric element 120 to the mass body 130.

Further, referring to FIG. 1, the mass body 130 may be provided with a support portion 134 protruded radially outwardly from a lower portion of the mass body 130 and the support portion 134 may be joined to the second elastic member 150.

However, as illustrated in FIG. 3, the second elastic member 150 may be joined to a top surface of the mass body 130 and the housing 110 to elastically support the mass body 130.

Here, when a radial surface of the housing 110 is attached to a vibrated body such as a body of a portable electronic device, the mass body 130 may be vibrated in a vertical direction with respect to the vibrated body through elastic force of the first elastic member and the second elastic member.

Further, when a vertical surface of the housing 110 is attached to the vibrated body, the mass body 130 may be vibrated radially with respect to the vibrated body.

Here, the radial surface of the housing 110 may refer to the bottom surface of the housing 110 and the vertical surface of the housing 110 may refer to a side of the housing 110.

The piezoelectric element 120 may be an element that generates voltage when mechanical input is applied thereto and causes mechanical deformation when voltage is applied thereto, and may be an element having properties in which a potential difference is generated due to electric polarization generated when en external force is applied thereto but deformation or deformation force is generated when voltage is applied thereto.

Therefore, the vibrating actuator 100 according to the embodiment of the present invention may obtain a vibrational force throughvoltage being applied to the piezoelectric element 120 to convert electrical energy into mechanical energy and may include a separate circuit board for applying voltage to the piezoelectric element 120.

The piezoelectric element 120 may be configured to include a lower electrode 126 that serves as a common electrode, a piezoelectric layer 124 deformed according to an application of voltage, and an upper electrode 122 that serves as a driving electrode.

The piezoelectric layer 124 may be formed of a piezoelectric material, specifically, a lead zirconate titanate (PZT) ceramic material. In addition, as piezoelectric materials, quartz, tourmaline, rochelle salt, barium titanate, monoammonium phosphate, tartaric acid ethylenediamine, and the like, may be used.

The piezoelectric element 120 may be disposed below the mass body 130, and in detail, may be disposed below the mass body 130 so as to be spaced apart from the mass body 130 by a predetermined distance.

Here, the piezoelectric element 120 may be mounted on a portion of an inner surface of the housing 110.

The first elastic member 140 elastically supporting the mass body 130 may be disposed between the piezoelectric element 120 and the mass body 130.

That is, a top surface of the first elastic member 140 may be joined to the mass body 130 and a bottom surface thereof may be joined to the piezoelectric element 120.

Therefore, the first elastic member 140 may transfer the vibrational force from the piezoelectric element 120 to the mass body 130 to vibrate the mass body 130.

Further, as illustrated in FIG. 1, the second elastic member 150 may have one end joined to the housing 110 and the other end joined to the support portion 134 of the mass body 130 to elastically support the mass body 130.

That is, in the embodiment of the present invention, the medium of vibration may be configured of the first elastic member 140 and the second elastic member 150.

Here, a natural vibration frequency of the first elastic member 140 and the second elastic member 150 may correspond to an operating frequency of the piezoelectric element 120.

This is to significantly increase the vibration force transferred to the mass body 130 to obtain a large quantity of vibrations.

Referring to FIG. 3, the first elastic member 140 may contact the top surface of the piezoelectric element 120 and the contact preventing portion 132 of the mass body 130 to elastically support the mass body 130.

Therefore, a distance between the mass body 130 and the piezoelectric element 120 may be filled with the first elastic member 140.

In addition, one end of the second elastic member 150 may be joined to the housing 110 and the other end thereof may be joined to the top surface of the mass body 130 to elastically support the mass body 130.

FIG. 4 is a schematic cross-sectional view illustrating a vibrating actuator according to a second embodiment of the present invention.

Referring to FIG. 4, a vibrating actuator 200 according to a second embodiment of the present invention is the same as the vibrating actuator 100 according to the first embodiment except for a mass body 230 and a second elastic member 250 and therefore, the description other than the mass body 230 and the second elastic member 250 will be omitted.

A shape of a radial cross section of the mass body 230 may be variously formed to have a circular, a rectangular, a regular square, a ring shape, and the like, according to the shape of the housing 110 and the internal components.

Further, in order to prevent a piezoelectric element 220 mounted on a portion of an inner surface of the housing 210 from coming into contact with the mass body 230 during the vibration process, a contact preventing portion 232 in which at least a portion of the bottom surface of the mass body 230 is recessed upwardly may be provided.

Therefore, the mass body 230 and the piezoelectric element 220 may be disposed so as to be spaced apart from each other by a predetermined distance.

A top surface of the mass body 230 is provided with a groove 234 in a circumferential direction so that the second elastic member 250 may be accommodated in the groove 234, wherein the groove 234 may be configured to guide the second elastic member 250.

That is, one end of the second elastic member 250 may be joined to the housing 210 and the other end thereof may be accommodated in the groove 234 so as to be joined to the mass body 230, thereby elastically supporting the mass body 230.

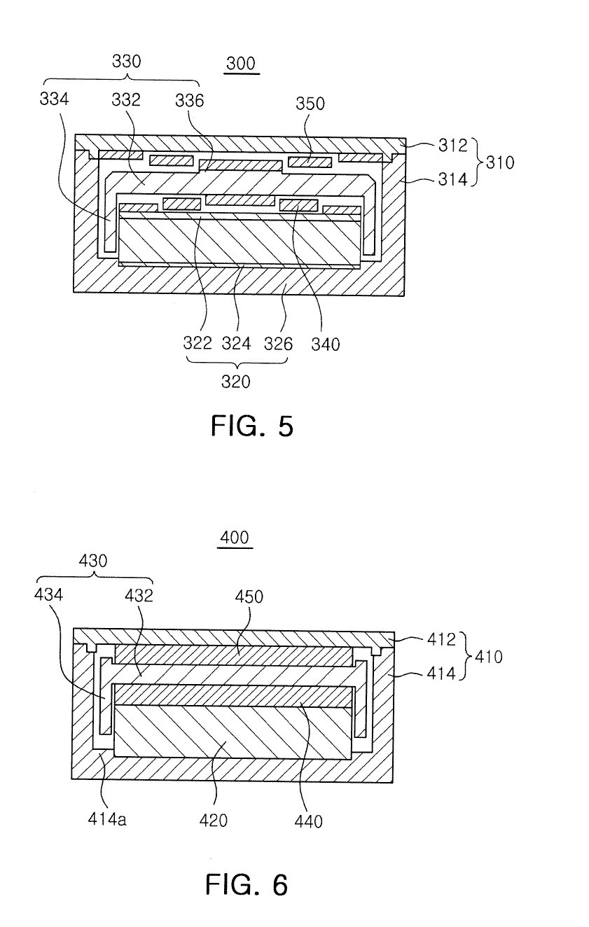

FIG. 5 is a schematic cross-sectional view illustrating a vibrating actuator according to a third embodiment of the present invention.

Referring to FIG. 5, a vibrating actuator 300 according to a third embodiment of the present invention is the same as the vibrating actuator 100 according to the first embodiment except for a mass body 330, a first elastic member 340 and a second elastic member 350, and therefore, the description other than the mass body 330, the first elastic member 340, and the second elastic member 350 will be omitted.

The mass body 330 may include a horizontal portion 332 and an extension 334 extending downwardly from an outside of the horizontal portion 332.

An inner diameter of the extension 334 may be larger than an outer diameter of the piezoelectric element 320 and as a result, the piezoelectric element 320 may be prevented from coming into contact with the extension 334 during the vibration process.

Further, the mass body 330 may be provided with a protrusion 336 formed by upwardly protruding at least a portion of the top surface of the mass body 330 so as to be joined to the second elastic member 350, and the protrusion 336 may be joined to the second elastic member 350.

The first elastic member 340 is disposed between the mass body 330 and the piezoelectric element 320, and one end thereof may be joined to the mass body 330 and the other end thereof may be joined to the piezoelectric element 320 to elastically support the mass body 330.

The second elastic member 350 may be disposed between the housing 310 and the mass body 330 and one ends thereof may be joined to the housing 310 and the other end thereof is joined to the protrusion 336 of the mass body 330 to elastically support the mass body 330.

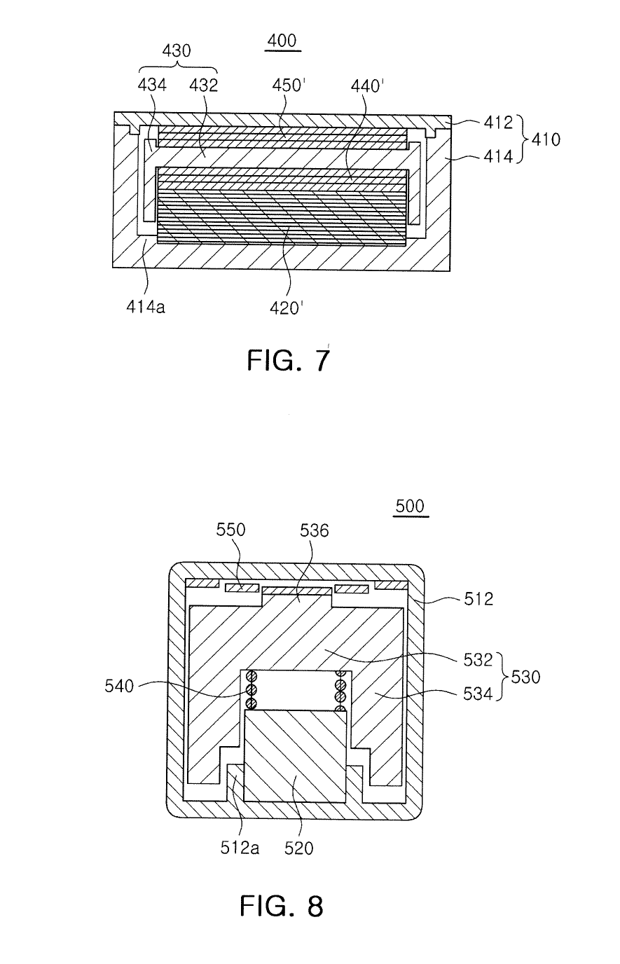

FIG. 6 is a schematic cross-sectional view illustrating a vibrating actuator according to a fourth embodiment of the present invention and FIG. 7 is a schematic cross-sectional view illustrating a modification of a piezoelectric element, a first elastic member, and a second elastic member of the vibrating actuator according to the fourth embodiment of the present invention.

Referring to FIGS. 6 and 7, a vibrating actuator 400 according to a fourth embodiment of the present invention is the same as the vibrating actuator 100 according to the first embodiment except for amass body 430, a piezoelectric element 420, a first elastic member 440, and a second elastic member 450, and therefore, the description other than the mass body 430, the piezoelectric element 420, the first elastic member 440, and the second elastic member 450 will be omitted.

The mass body 430 may be provided with a horizontal portion 432 and a vertical portion 434 extending axially upwardly and downwardly from an outside of the horizontal portion 432.

An inner diameter of the vertical portion 434 may be larger than an outer diameter of the piezoelectric element 420 and as a result, the piezoelectric element 420 may be prevented from being in contact with the vertical portion 434 during the vibration process.

The first elastic member 440 may be in contact with the top surface of the piezoelectric element 420 and the bottom surface of the horizontal portion 432 and may elastically support the mass body 430.

Further, the second elastic member 450 may be in contact with the other surface inside the housing 410 and the top surface of the horizontal portion 432 and may elastically support the mass body 430.

Here, the second elastic member 450 may have an outer diameter corresponding to an inner diameter of the vertical portion 434 and may be inserted into the vertical portion 434 so as to be firmly joined to the mass body 430.

Referring to FIG. 7, the piezoelectric element 420 may be formed by overlapping a plurality of piezoelectric layers.

That is, the piezoelectric element 420 may be configured of a single piezoelectric layer and may also be configured of a plurality of overlapping piezoelectric layers, but when the piezoelectric element 420 is configured of the plurality of piezoelectric layers, a relatively larger degree of vibrational force may be obtained.

In addition, the first elastic member 440 and the second elastic member 450 may be configured of layers of several elastic materials.

That is, the first elastic member 440 and the second elastic member 450 may be formed of a single elastic material, but as illustrated in FIG. 7, may be configured of layers of several elastic materials.

FIG. 8 is a schematic cross-sectional view illustrating a vibrating actuator according to a fifth embodiment of the present invention.

Referring to FIG. 8, a vibrating actuator 500 according to a fifth embodiment of the present invention is the same as the vibrating actuator 100 according to the first embodiment except for a mass body 530, a first elastic member 540, and a second elastic member 550 and therefore, the description other than the mass body 530, the first elastic member 540, and the second elastic member 550 will be omitted.

The mass body 530 may include a horizontal portion 532 and an extension 534 extending downwardly from an outside of the horizontal portion 532.

An inner diameter of the extension 534 may be larger than an outer diameter of the piezoelectric element 520 and as a result, the piezoelectric element 520 may be prevented from coming into contact with the extension 534 during the vibration process.

Further, in order to prevent an outer wall 512a into which the piezoelectric element 520 is inserted from coming into contact with the extension 534 during the vibration process, a step may be formed radially outwardly at the bottom portion of the extension 534.

Further, the mass body 530 may be provided with a protrusion 536 formed by upwardly protruding at least a portion of the top surface of the mass body 530 so as to be joined to the second elastic member 550, and the protrusion 536 may be joined to the second elastic member 550.

The first elastic member 540 is disposed between the mass body 530 and the piezoelectric element 520, and one end thereof may be joined to the mass body 530 and the other end thereof may be joined to the piezoelectric element 520 to elastically support the mass body 530.

The second elastic member 550 may be disposed between the housing 510 and the mass body 530, and one ends thereof may be joined to the housing 510 and the other end thereof is joined to the protrusion 536 of the mass body 530 to elastically support the mass body 530.

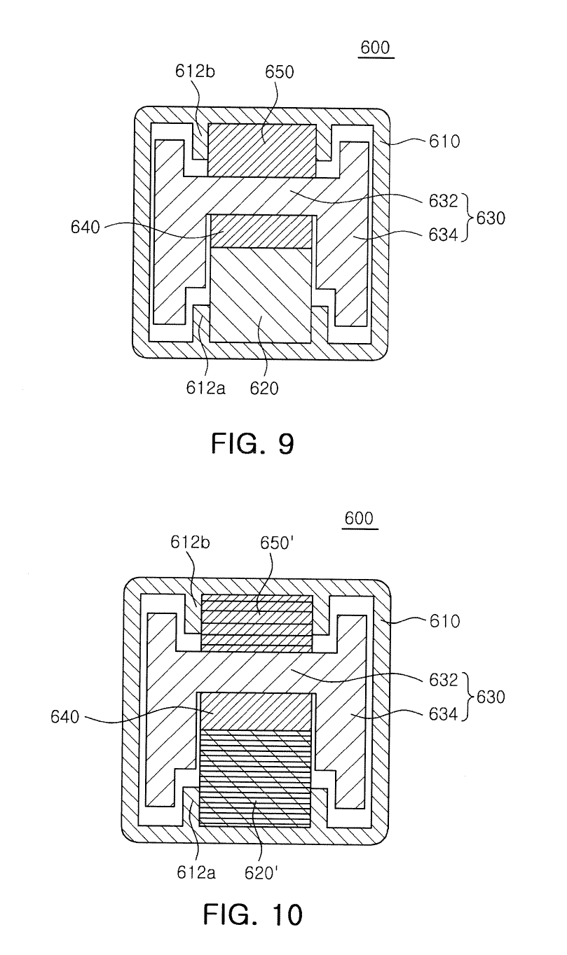

FIG. 9 is a schematic cross-sectional view illustrating a vibrating actuator according to a sixth embodiment of the present invention and FIG. 10 is a schematic cross-sectional view illustrating a modification of a piezoelectric element and a second elastic member of the vibrating actuator according to the sixth embodiment of the present invention.

Referring to FIGS. 9 and 10, a vibrating actuator 600 according to a sixth embodiment of the present invention is the same as the vibrating actuator 500 according to the fifth embodiment except for a protrusion 612b of a housing 610, a mass body 630, a first elastic member 640, and a second elastic member 650, and therefore, the description other than the protrusion 612b of the housing 610, the mass body 630, the first elastic member 640, and the second elastic member 650 will be omitted.

The mass body 630 may include a horizontal portion 632 and a vertical portion 634 extending upwardly and downwardly from an outside of the horizontal portion 632.

The other surface inside the housing 610 is provided with the protrusion 612b protruded to correspond to an outer diameter of the second elastic member 650 so that the second elastic member 650 is inserted into an inner surface of the protrusion 612b, thereby more firmly joining the second elastic member 650 to the other surface inside the housing 610.

The outer diameter of the protrusion 612b may be smaller than the inner diameter of the vertical portion 634 and as a result, the vertical portion 634 may be prevented from coming into contact with the protrusion 612b during the vibration process.

The first elastic member 640 may be in contact with the top surface of the piezoelectric element 620 and the bottom surface of the horizontal portion 632, and may elastically support the mass body 630.

Further, the second elastic member 650 may be in contact with the other surface inside the housing 610 and the top surface of the horizontal portion 632 and may elastically support the mass body 630.

Here, the second elastic member 650 may have an outer diameter corresponding to an inner diameter of the protrusion 612b and may be inserted into the protrusion 612b so as to be firmly joined to the housing 610.

Referring to FIG. 10, the piezoelectric element may be formed by overlapping the plurality of piezoelectric layers.

That is, the piezoelectric element 620′ may be configured of a single piezoelectric layer and may also be configured of a plurality of overlapping piezoelectric layers, but when a piezoelectric element 620′ is configured of the plurality of piezoelectric layers, a relatively larger degree of vibrational force may be obtained.

In addition, a second elastic member 650′ may be configured of layers of several elastic materials.

That is, the second elastic member 650′ may be formed of a single elastic material, but as illustrated in FIG. 10, may also be configured of layers of several elastic materials.

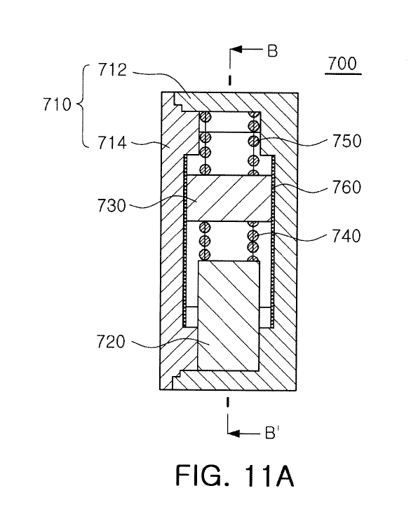

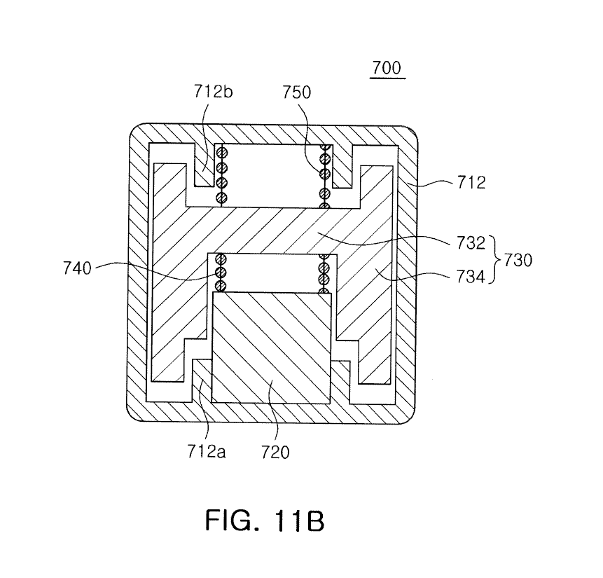

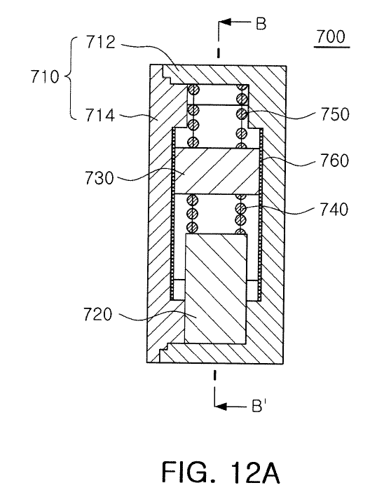

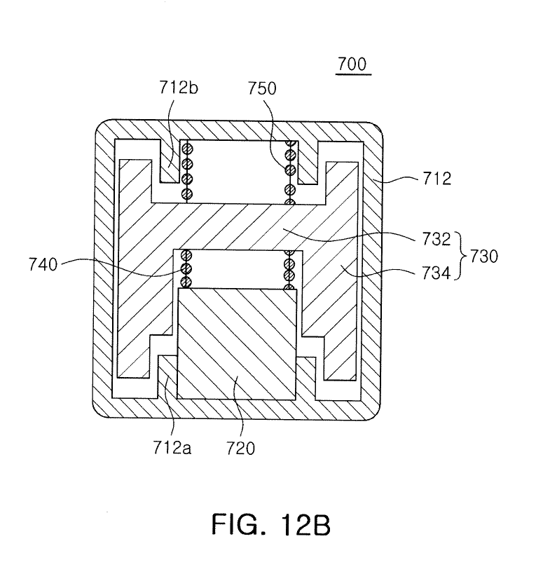

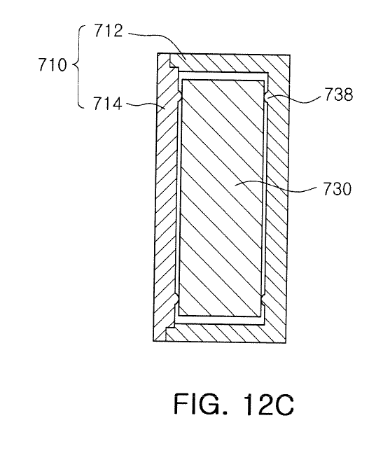

FIG. 11A is a schematic side cross-sectional view illustrating an appearance in which a vibrating actuator according to a seventh embodiment of the present invention further includes a sliding film, FIG. 11B is a cross-sectional view taken along line B-B′ of FIG. 11A, FIG. 12A is a schematic side cross-sectional view illustrating the vibrating actuator according to the seventh embodiment of the present invention, FIG. 12B is a cross-sectional view taken along line C-C′ of FIG. 12A, and FIG. 12C is a schematic cross-sectional view illustrating an appearance in which the vibrating actuator according to the seventh embodiment of the present invention further includes a guide portion.

Referring to FIGS. 11A through 12C, a vibrating actuator 700 according to the seventh embodiment of the present invention is the same as the vibrating actuator 600 according to the sixth embodiment except for a sliding film 760 and a guide portion 734 and therefore, the description other than the sliding film 760 and the guide portion 734 will be omitted.

Referring to FIGS. 11A and 11B, the mass body 730 may be provided to have an outer diameter smaller than an inner diameter with respect to an inner circumferential surface of the housing 710 and therefore, a gap having a predetermined size may be formed between the inner circumferential surface of the housing 710 and the outer circumferential surface of the mass body 730.

The gap between the outer circumferential surface of the mass body 730 and the inner circumferential surface of the housing 710 may be provided with the sliding film 760.

Therefore, when the mass body 730 is vibrated, the mass body 730 may be smoothly vibrated by the sliding film 760 without friction.

With reference to FIGS. 12A through 12C, the inner surface of the housing 710 may be provided with the guide portion 734 protruded to point-contact the mass body 630.

Therefore, as illustrated in FIG. 12B, when the mass body 730 is vibrated, the guide portion 734 may point-contact the mass body 730 and therefore, may perform a guiding function so that the vibrating direction of the mass body 730 is constant.

Further, the guide portion may point-contact the mass body to significantly reduce the friction with the mass body.

According to the embodiments of the present invention, the vibrating actuator according to the embodiments of the present invention may use the piezoelectric element to reduce power consumption, reduce the number of internal components to simplify the assembling process, and support the mass body using two elastic members to significantly increase the vibration force.

In addition, the shape of the housing and the mass body may be variously changed and therefore, the miniaturization and the slimness of portable electronic devices may be satisfied.

As set forth above, according to the vibrating actuator of the present invention, the miniaturization and slimness of the portable electronic devices may be satisfied, the vibration quantity may be increased, and power consumption may be reduced.

Further, the assembling process may be simplified by reducing the number of internal components.

While the present invention has been shown and described in connection with the embodiments, it will be apparent to those skilled in the art that modifications and variations can be made without departing from the spirit and scope of the invention as defined by the appended claims.

What is claimed is:

1. A vibrating actuator, comprising:
a housing including an inner space;
a piezoelectric element mounted on a portion of an inner surface of the housing;
a mass body disposed above the piezoelectric element;
a first elastic member disposed between the piezoelectric element and the mass body to elastically support the mass body; and
a second elastic member having one end joined to the housing and the other end joined to the mass body to elastically support the mass body.

2. The vibrating actuator of claim 1, wherein the piezoelectric element is configured of a single piezoelectric layer.

3. The vibrating actuator of claim 1, wherein the piezoelectric element is configured of a plurality of piezoelectric layers.

4. The vibrating actuator of claim 1, wherein the portion of the inner surface of the housing is provided with an outer wall protruded to correspond to an outer diameter of the piezoelectric element.

5. The vibrating actuator of claim 1, wherein the mass body is provided with a contact preventing portion in which at least a portion of a bottom surface of the mass body is recessed upwardly.

6. The vibrating actuator of claim 1, wherein a radial surface of the housing is attached to a vibrated body and the mass body is vibrated vertically with respect to the vibrated body.

7. The vibrating actuator of claim 1, wherein a vertical surface of the housing is attached to the vibrated body and the mass body is vibrated radially with respect to the vibrated body.

8. The vibrating actuator of claim 1, wherein the mass body is provided with a support portion protruded radially outwardly from a lower portion of the mass body.

9. The vibrating actuator of claim 8, wherein the second elastic member is joined to the support portion.

10. The vibrating actuator of claim 1, wherein a top surface of the mass body is provided with a groove provided in a circumferential direction and the second elastic member is accommodated in the groove.

11. The vibrating actuator of claim 1, wherein the mass body is provided with a protrusion formed by upwardly protruding at least one of the top surface of the mass body, and the protrusion is joined to the second elastic member.

12. The vibrating actuator of claim 1, wherein the mass body includes a horizontal portion and a vertical portion extending axially upwardly and downwardly from an outside of the horizontal portion.

13. The vibrating actuator of claim 12, wherein the other surface inside the housing is provided with a protrusion protruded to have an outer diameter smaller than an inner diameter of the vertical portion.

14. A vibrating actuator, comprising:
a housing including an inner space;
a piezoelectric element mounted on a portion of an inner surface of the housing;
a mass body disposed above the piezoelectric element;
a first elastic member contacting the piezoelectric element and the mass body to elastically support the mass body; and
a second elastic member contacting the mass body and the housing to elastically support the mass body.

15. The vibrating actuator of claim 14, wherein the mass body includes a horizontal portion and a vertical portion extending axially upwardly and downwardly from both ends of the horizontal portion.

16. The vibrating actuator of claim 15, wherein the mass body and the housing include a sliding film interposed therebetween.

17. The vibrating actuator of claim 14, wherein an inner surface of the housing is provided with a guide portion protruded so as to point-contact the mass body.

18. The vibrating actuator of claim 14, wherein the other surface inside the housing is provided with a protrusion corresponding to an outer diameter of the second elastic member, and the inner surface of the protrusion have the second elastic member inserted thereinto.
